(19) United States
(12) Patent Application Publication
(10) Pub. No.: US 2025/0335757 A1
(43) Pub. Date: Oct. 30, 2025

(54) NEURAL NETWORK OF BINARY NEURONS

(71) Applicant: Commissariat à l'Energie Atomique et aux Energies Alternatives, PARIS (FR)

(72) Inventors: William GUICQUERO, GRENOBLE (FR); Nicolas PELLETIER, GRENOBLE (FR)

(21) Appl. No.: 19/183,653

(22) Filed: Apr. 18, 2025

(30) Foreign Application Priority Data
Apr. 25, 2024 (FR) 2404299

(51) Int. Cl. G06N 3/065

(52) U.S. Cl. CPC G06N 3/065

(57) ABSTRACT

The present disclosure relates to a circuit comprising a first memory element configured to store a first data value; a second memory element configured to store a weight matrix in association with a layer of a binary neural network; and a computing circuit configured to: a) receive the first data value and the k-th row of the weight matrix; b) receive a first control signal, indicating the nature of each of the first and second read functions, each associated with two-valued arithmetic; c) generate a first vector by applying the first read function to the k-th row of the weight matrix and a second vector by applying the second read function to the data; and d) generate a k-th component of a first output vector based on the first and second vectors.

### FIELD

The present disclosure generally relates to circuits configured to perform binary neural networks, and more particularly to the near-memory implementation of such networks.

### BACKGROUND

Operators, such as scalar products or Hadamard products, are generally involved in the operation of binary neural networks. These operators are used, for example, on each layer of the network, and the operator outputs are binarized or requantized.

When the neural network has as a hardware porting, a so-called “near-memory” architecture, the operators are placed directly at the memory output, for example at the edge of a memory tile of the SRAM (Static Random Access Memory) type. In order to save space, it is desirable to increase the activity rate of these operators during network execution. Similarly, the arithmetic used, i.e. the definition of the space of useful numbers, their relationships and properties, as well as the elementary mathematical operations that can be performed, is the same for all network layers.

In addition, some networks incorporate gating mechanisms so as to encourage the emergence of an attention-like mechanism. These mechanisms are generally implemented via activation functions working from the space of real numbers to the space of real numbers, such as softmax and/or sigmoid functions, followed by a computationally expensive stage of point-to-point multiplication.

There is a need to improve near-memory binary neural network architectures, particularly in terms of performance, power consumption, and surface area.

### SUMMARY

One embodiment provides a circuit comprising:
a first memory element configured to store a first data value;
a second memory element configured to store a first weight matrix in association with a first layer of an artificial binary neural network; and
a computing circuit configured to:
   a) receive the first data value and the k-th row, from the first weight matrix;
   b) receive a first control signal, indicating the nature of each of the first and second read functions, among at least the first and second reference functions, the first and second reference functions each being associated with two-valued arithmetic;
   c) generate a first vector by applying the first read function to the k-th row of the first weight matrix and a second vector by applying the second read function to the first data value; and
   d) generate a k-th component of a first output vector based on the first and second vectors.

According to one embodiment, the first reference function has values in {−1,1} and the second reference function has values in {0,1}.

According to one embodiment, the above circuit is configured to, following the generation of the k-th component of the first output vector, control the storage of the k-th component in the first memory element.

According to one embodiment, the above circuit further comprises:
a first logic gate configured to apply an operation of AND type between the k-th component of the first output vector, forwarded by the computing circuit, and a component of a binary vector;
a second logic gate configured to apply an XNOR-type operation between the k-th component of the first vector, forwarded by the computing circuit, and the component of the binary vector;
a first multiplexer configured to select the output of the first logic gate, or the output of the second logic gate, on the basis of a control signal, indicating the nature of a third read function among the first and second reference functions;
a second multiplexer configured to generate a k-th component of a second output vector by selecting the k-th component of the first vector, supplied by the computing circuit, or the output of the first multiplexer, on the basis of a modulation signal.

According to one embodiment, the above circuit further comprises a scheduler circuit configured to:
receive a component of a vector stored in the first memory element; and
on the basis of the value of the component, cause the reading, from the second memory element, of the k-th row of the first weight matrix.

According to one embodiment, the computing circuit comprises:
a number N of multiplier circuits each configured to receive the first and second read functions and each configured to generate an output scalar based on a component of a vector and a component of a weight matrix;
an accumulator circuit configured to sum the output scalars provided by the plurality of multiplier circuits; and
a converter configured to convert the value generated by the accumulator circuit into a binary value.

According to one embodiment, the accumulator comprises an adder tree, comprising a plurality of shift circuits and configured to generate a scalar, corresponding to the scalar product between the first and second vectors, increased by a gain being a power of 2.

According to one embodiment, the first data value is of length N, N being an integer, and is stored contiguously by vectors of lengths K, K being a divisor of the value N, and wherein the k-th row, of the first matrix is of length N, and wherein the computing circuit comprises a number L=N/K of shift registers coupled to the first memory element and is configured to, following receipt of a sequence of vectors of the first data value, convert said first data value into a vector of size N, by concatenation of vectors of size K, wherein the shift registers are, for example, further configured to perform concatenation of the first data value of size K with a sequence of N−K bits each equal to 1, or 0.

According to one embodiment each of the multiplier circuits comprises a logic gate of NXOR and/or AND-type configured to multiply a component of the first data value and an element of the first weight matrix associated with the first layer.

According to one embodiment, the first memory element is further configured to store a masking vector, the scheduler circuit being configured to:
if the k-th component of the masking vector is equal to 0, control the storage of the k-th component of the first data value as the k-th component of the first output vector; and
if the k-th component of the masking vector is equal to 0, control the execution of steps a) to c).

According to one embodiment the first memory element is a memory configured to implement masking operations.

According to one embodiment, the second memory element further stores a third weight matrix associated with a second layer of the neural network, and wherein the computing circuit is further configured to:
select, following reception of a second control signal, fifth and sixth read functions, from the first and second reference functions;
generate a fifth vector by applying the fifth read function to a row, or column, of the third weight matrix and a sixth vector by applying the sixth read function to an output vector of a previous layer, stored in the first memory element;
generate a third output value based on the fifth and sixth vectors.

According to one embodiment, the first reference function is defined by g: u=→u, and the second reference function is defined by h:u→2u−1.

One embodiment provides a method comprising:
supplying a first data value stored in a first memory element of a circuit and the k-th row of a first weight matrix associated with a layer of a binary artificial neural network to a first computing circuit of the circuit;
providing an indication, via a control signal, of the nature of a first and a second read function, among a first and a second reference function;
generating, by the first computing circuit, a first vector by applying the first function to the k-th row of the weight matrix, and a second vector by applying the second function to the first data value,
generating a k-th component of a first output vector on the basis of the first and second vectors,
   the first and second reference functions each associated with two-valued arithmetic.

According to one embodiment, the first computing circuit comprises a plurality of multiplier circuits and an accumulator configured to generate a scalar by performing a scalar product between the first and second vectors, wherein, the first computing circuit comprises, for example, a converter configured to convert the scalar into a binary value.

According to one embodiment, the above method further comprises:
reading, by a second circuit for computing the value of a first component of the first data value, the first output value and a first masking value, stored in the first memory element; and
controlling, on the basis of the first masking value and by the second computing circuit, the writing of a first masked value, into the first memory element, corresponding either to the first component of the first data value, or to the k-th component of the first output vector.

According to one embodiment, writing the first masked value comprises:
deleting the first component of the first data value; and
writing the first masked value to the address of the first component of the first data value into the first memory element.

According to one embodiment, the above method further comprises, after writing the first masked value:
generating a k+1-th output component of the first output vector, and storing it in the first memory element;
reading, by the second circuit for computing the value of a k+1-th component of the first data value, the k+1-th component of the first output vector and a second masked value, stored in the first memory element; and
controlling, on the basis of the second masking value and by the second computing circuit, the writing of a second masked value, into the first memory element, corresponding either to the k+1-th component of the first data value, or to the k+1-th component of the output vector.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a block diagram illustrating a rebinarized scalar product in a layer of a neural network;

FIG. 2 is a block diagram illustrating an example near-memory architecture of a fully-connected network, according to one embodiment of the present description;

FIG. 3 is a diagram illustrating an example implementation of a requantized scalar product operator;

FIG. 4A is a diagram illustrating an example adder tree, according to one embodiment of the present description;

FIG. 4B is a diagram illustrating an example programmable bit shift circuit of the adder tree shown in FIG. 4A, according to one embodiment of the present description;

FIG. 5 is a block diagram illustrating a scalar product rebinarized in a layer of a neural network, followed by a modulation operation;

FIG. 6 is a block diagram illustrating an example fully-connected layer circuit incorporating a modulation mechanism on an output vector, according to one embodiment of the present description;

FIG. 7A schematically illustrates a sequence of operations allowing a binary masking mechanism to be implemented;

FIG. 7B schematically illustrates another example sequence of operations for reading from/writing into a memory circuit allowing a masking mechanism to be performed; and

FIG. 8 is a block diagram illustrating an example fully-connected layer circuit incorporating a modulation mechanism on a vector coming from an intermediate computation, and allowing a masking mechanism to be performed by conditionally updating the output vector, according to one embodiment of the present description.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, those skilled in the art knows the operation and implementation of artificial neuronal networks, and especially of binary neuronal networks, which have not been described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

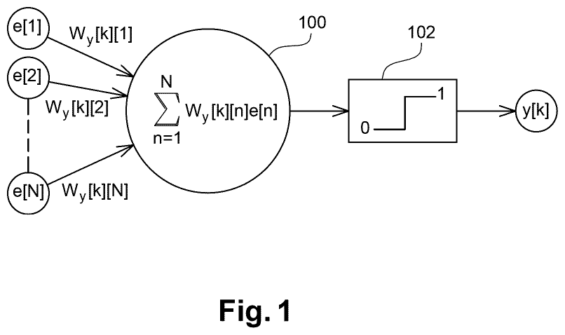

FIG. 1 is a block diagram illustrating a rebinarized scalar product in a layer of a neural network.

By way of example, a vector e=(e[1], e[2], . . . , e[N]), of size N, N being an integer greater than or equal to 1, is an input vector for a layer of the neural network. Each component e[n], n∈{1, . . . , N}, is a binary value, equal to 0 or 1. Depending on the type of binary arithmetic chosen, binary values 0 and 1 respectively quantify either values equal to 0 and 1, or values equal to −1 and 1, or two other values e.g. equal to 0 and 2 or −2 and 2, etc.

By way of example, a layer operation allows a layer output vector y=(y[1], y[2], . . . , y[K]), of size K, where N is a multiple of K, to be generated. Each component y[k], k∈{1, . . . , K}, of the layer output vector is then equal to the scalar product 100 between the input vector e and a row W_{y}[k] of a binarized weight matrix W_{y}, for example through an activation function 102.

By way of example, the scalar product 100 is a component y[k] defined as the sum of the point-to-point multiplication of the vector e with the vector W_{y}[k]. In other words

$$\hat{y} [ k ] = {\sum }_{n = 1}^{N} {W}_{y} [ k ] [ n ] e [ n ] ,$$

where W_{y}[k][n] is the coefficient in the k-th row, n-th column of the matrix W_{y}. By way of example, each weight of the weight matrix W_{y} is a binary value, where the value 1 quantifies a value equal to 1, and the value 0 quantifies a value equal to 0 or, for example, −1, etc., depending on the arithmetic used.

The component y[k] is then obtained, for example, by applying a binarization function b to the value y[k], so as to transform the value y[k] into a binary value. In other words y[k]=b(ŷ[k]). By way of example, the function b is defined by:

$$b ( x ) = \{ \begin{matrix}1 & si x > 0 \\ 0 & si x \leq 0\end{matrix} . \qquad [ Math 1 ]$$

In another example, a bias value is added to the scalar product 100, and in this case, the value provided to the function b is equal to

$$\hat{y} [ k ] = {\sum }_{n = 1}^{N} {W}_{y} [ k ] [ n ] e [ n ] + Bias [ k ] ,$$

where Bias[k] is a bias value for the k-th component. By way of example, for any k∈{1, . . . , K}, Bias[k] is a constant value, not dependent on the value of the index k.

By way of example, the binarization function b is implemented as hardware by a comparator, or by an ADC-1b (Single bit Analog to Digital Converter).

Each component y[k] of the layer output vector y is therefore a binary value, belonging to {0,1}. By way of example, depending on the arithmetic considered, the value 0 quantizes a value equal to 0, or a value equal, for example, to −1.

According to one embodiment, in order to take into account the arithmetic(s) under consideration, the scalar product 100 is computed using read functions. By way of example, the read functions are functions which take as input a binary value, equal to 0 or 1, and are configured to output a value belonging, for example, to the set {0,1} or to the set {−1, 1}. In other words, read functions enable the binary value encoding an input, weight or output value to be transformed into a value in another representation.

By way of example, the read functions are among a sign function g, defined by g: u→2u−1, and a function h of the so-called Heaviside, and defined by h:u→u. In this way, using reading functions allows arithmetic to be obtained in {−1, 1} for the function g and/or in {0, 1} for the function h. In the remainder of the description, the function

$${f}_{y}^{( W )} ( {W}_{y} )$$

will represent the read function applied to the weight matrix of the current layer for computing the output y, and the quantity

$${f}_{y}^{( W )}$$

represents a matrix, of the same size as the weight matrix W_{y}, and, for any (n,k)∈{1, . . . , N}× {1, . . . , K},

$${f}_{y}^{( W )} ( {W}_{y} ) [ k ] [ n ] = {f}_{y}^{( W )} ( {W}_{y} [ k ] [ n ] ) .$$

Similarly, the function

$${f}_{y}^{( e )}$$

will represent the read function applied to the input vector e of the current layer for computing the output y, and the quantity

$${f}_{y}^{( e )} ( e )$$

represents a vector, of the same size as the vector e, and, for any n∈{1, . . . , N},

$${f}_{y}^{( e )} ( e ) [ n ] = {f}_{y}^{( 1 )} ( e [ n ] ) .$$

For each layer, and therefore for each layer output y, each of the functions

$${f}_{y}^{( W )}$$

and ƒ^{(e)} is, in this example, either equal to the function g or to the function h. In this way, the read functions

$${f}_{y}^{( W )} and {f}_{y}^{( e )}$$

enable scalar products on each layer to take place, for example, in the sets {0,1}^{N}×{0,1}^{N}, {0,1}^{N}×{−1,1}^{N}, and/or {−1,1}^{N}×{−1,1}^{N}. These sets are given by way of example, other arithmetic methods are of course conceivable, in which case the read functions will have to be adapted by those skilled in the art in order to have values in the desired sets. In the following description, for any vector u occurring in a layer operation, read functions

$${f}_{u}^{( W )} and {f}_{u}^{( e )}$$

are read functions among the functions g and h used in computing the vector u. The scalar product between the two vectors

$${f}_{y}^{( e )} ( e ) and {f}_{y}^{( W )} ( {W}_{y} [ k ] )$$

is then denoted

$${f}_{y}^{( e )} ( e ) {f}_{y}^{( W )} ( {W}_{y} [ k ] ) .$$

According to one embodiment, considering that each of the components of the input vector e, as well as each of the coefficients of the weight matrix W_{y}, are binary values, in {0,1}, the layer output vector y is such that

$$y = b ( {f}_{y}^{( W )} ( {W}_{y} ) {f}_{y}^{( e )} ( e ) ) ,$$

where

$${f}_{y}^{( W )} ( {W}_{y} ) {f}_{y}^{( e )} ( e )$$

is a vector of size K, each component of which is equal to the scalar product between the vector e and a row of the weight matrix W_{y}. The output vector is therefore also binary-valued in {0,1}^{K}.

By way of example, the layer output vector y for a current layer is an input vector for a subsequent layer. By way of example, for this next layer, the arithmetic representing the input vector y is different from that representing the input vector e for a current layer. Similarly, in one example, the weight matrix for this next layer has a different representation to that of the matrix W_{y} for the current layer. In another example, the representations of the vector y and/or the weight matrix for this next layer are the same as the representations of the vector e and/or the matrix W_{y} for the current layer. The reading functions used from one layer to the next may therefore vary.

According to one embodiment, one or more layers of the neural network are configured to further apply a gating or attention-like operation. The gating operation masks, for example, some components of the layer output vector y. A masked vector is then supplied as input data to the next layer in the network. Masking operations enable outputs to be selected and/or modulated according to a context, or to a previous classification.

According to one embodiment, an output vector s, obtained by masking the output vector y, is defined by:

$$s = \overline{z} \cdot x + z \cdot y , \qquad [ Math 1 ]$$

where the operator “·” represents a Hadamard product, or point-by-point product, and where the vector x with values in {0,1}^{K} is derived from the input vector e, and/or from internal and/or intermediate states previously computed in the current layer, or in a previous layer. In particular, the operator “.” represents a modulation operation. The vector z is a binary vector, with values in {0,1}^{K}, and is a masking vector. The vector z̅ corresponds to the vector which, when summed with the vector z, results in a vector composed solely of 1. Thus, the vectors comprise some of its components from the vector x and the other of its components from the output vector y. The above-mentioned masking operation is a masking operation of the “multiplexing” type. Other so-called masking operations can be performed by applying another function, for example by performing a modulation operation between 2 vectors with a vector having “all or nothing” properties, for example with “0” values.

According to one embodiment, s is such as s=z̅·x+z·y, where, for example,

$$z = b ( {f}_{z}^{( W )} ( {W}_{z} ) {f}_{z}^{( e )} ( e ) ) ,$$

W_{z} being a weight matrix,

$$x = b ( {f}_{x}^{( W )} ( {W}_{x} ) {f}_{x}^{( e )} ( e ) ) ,$$

Wₓ being another weight matrix, and where y is the output vector described above, or y=e. The functions

$${f}_{z}^{( W )} , {f}_{z}^{( e )} , {f}_{x}^{( W )} ,$$

$$and {f}_{x}^{( e )}$$

are readout functions, respectively associated with the vectors z and x and, for example, equal to the function g and/or the function h. Defined in this way, the vectors z, x and y are derived from projections of the vector e, or are directly equal to the vector e. The masking thus achieved makes it possible to adapt and take into account values obtained by projection from the past, the past being defined by the layer input vector.

By way of example, masking operations are generally performed in so-called recurrent neural networks (RNNs), where feedback is applied in computing the output vector s. Indeed, when processing a data vector, at each index t of this vector, the equations involved in recurrent neural networks generally use versions prior to the vector s computed at time t, i.e. for example vectors sₜ₋₁ and hₜ₋₁ computed at time t−1. In particular, this type of operation enables past states to be stored. Recurrent structures are, for example, analogous to infinite impulse response filtering.

According to one embodiment, a vector dₜ In {0,1}^{2N} is defined as the concatenation of an input vector eₜ in {0,1}^{N} of a layer of an RNN and a vector hₜ₋₁ in {0,1}^{N}, i.e. dₜ=concat(eₜ,hₜ₋₁) and a vector d′ₜ in {0,1}^{2N} is defined as the concatenation of the input vector eₜ in {0,1}^{N} and an output vector sₜ₋₁ in {0,1}^{N} of a layer of the RNN, i.e. d′ₜ=concat(eₜ,sₜ₋₁). Several variants of recurrent structures can be defined, based on read functions as described above.

By way of example, the following table shows the various vectors involved in layer operations in a Long Short-Term Memory (LSTM) network. In particular, each vector among vectors (z, r, o, y, x, s, h) has a binary value in {0,1}^{N}, and is associated with read functions enabling its description in another arithmetic. To this end, each matrix in the following table has a binary value in {0,1}^{N}×{0,1}^{2N}, and is associated with read functions enabling its description in another arithmetic.

TABLE 1
${z}_{t} = b ( {f}_{z}^{( W )} ( {W}_{z} ) {f}_{z}^{( e )} ( {d}_{t} ) )$
${r}_{t} = b ( {f}_{r}^{( W )} ( {W}_{z} ) {f}_{r}^{( e )} ( {d}_{t} ) )$
${o}_{t} = b ( {f}_{o}^{( W )} ( {W}_{o} ) {f}_{o}^{( e )} ( {d}_{t} ) )$
${y}_{t} = b ( {f}_{y}^{( W )} ( {W}_{y} ) {f}_{y}^{( e )} ( {d}_{t} ) )$
xₜ = b (fₓ (yₜ) · fₓ (rₜ)
sₜ = z̅ₜ · xₜ + zₜ · sₜ₋₁
hₜ = b(fₕ (sₜ) · fₕ (oₜ) )

In this example, as each read function can be selected from g and h. 2¹⁰ implementations are possible.

The following table shows the various vectors involved in the layering operations of an LSTM-type network.

TABLE 2
${z}_{t} = b ( {f}_{z}^{( W )} ( {W}_{z} ) {f}_{z}^{( e )} ( {d}_{t} ) )$
${r}_{t} = b ( {f}_{r}^{( W )} ( {W}_{r} ) {f}_{r}^{( e )} ( {d}_{t} ) )$
${o}_{t} = b ( {f}_{o}^{( W )} ( {W}_{o} ) {f}_{o}^{( e )} ( {d}_{t} ) )$
uₜ = concat({1, 1, · · · ,1}; rₜ)
yₜ = b (f_{y} (dₜ) · f_{y} (uₜ)
${x}_{t} = b ( {f}_{x}^{( W )} ( {W}_{x} ) {f}_{x}^{( e )} ( {y}_{t} ) )$
sₜ = z̅ₜ · xₜ + zₜ · sₜ₋₁
hₜ = b(fₕ (sₜ) · fₕ (oₜ))

In this example, as each read function can be selected from g and h. 2¹⁰ implementations are possible.

The following table shows various vectors involved in the layer operations in a Gated Recurrent Unit (GRU) network in a canonical variant.

TABLE 3
${z}_{t} = b ( {f}_{z}^{( W )} ( {W}_{z} ) {f}_{z}^{( e )} ( {d}_{t}^{′} ) )$
${r}_{t} = b ( {f}_{r}^{( W )} ( {W}_{z r} ) {f}_{r}^{( e )} ( {d}_{t}^{′} ) )$
uₜ = concat({1,1, · · · ,1}; rₜ)
yₜ = b (f_{y}(d′ₜ) · f_{y} (uₜ)
${x}_{t} = b ( {f}_{x}^{( W )} ( {W}_{x} ) {f}_{x}^{( e )} ( {y}_{t} ) )$
sₜ = z̅ₜ · xₜ + zₜ · sₜ₋₁

In this example, as each read function can be selected from g and h, 2⁷ implementations are possible.

The following table shows various vectors involved in the layer operations in a Minimal Gated Unit (MGU) network in a canonical variant.

TABLE 4
${z}_{t} = b ( {f}_{z}^{( W )} ( {W}_{z} ) {f}_{z}^{( e )} ( {d}_{t}^{′} ) )$
uₜ = concat({1,1, · · · , 1}; zₜ)
yₜ = b (f_{y} (d'ₜ) · f_{y} (uₜ)
${x}_{t} = b ( {f}_{x}^{( W )} ( {W}_{x} ) {f}_{x}^{( e )} ( {y}_{t} ) )$
sₜ = z̅ₜ · xₜ + zₜ · sₜ₋₁
${z}_{t} = b ( {f}_{z}^{( W )} ( {W}_{z} ) {f}_{z}^{( e )} ( {d}_{t}^{′} ) )$

In this example, as each read function can be selected from g and h, 2⁵ implementations are possible.

Each of the hereinabove tables Table 1 to Table 4 then presents examples of algorithms in which the vectors sₜ and/or hₜ are obtained following computations of several scalar products between intermediate vectors. Computing vectors sₜ and/or hₜ are performed in several steps, for example. First steps include generating, for example sequentially, one or more intermediate vectors. In some examples, intermediate vectors, such as the vector yₜ, are obtained by modulation, denoted by the operator “·” in tables Table 2 to Table 4. In some examples, vectors such as the vector sₜ, are obtained by masking operation in tables Table 1 to Table 4.

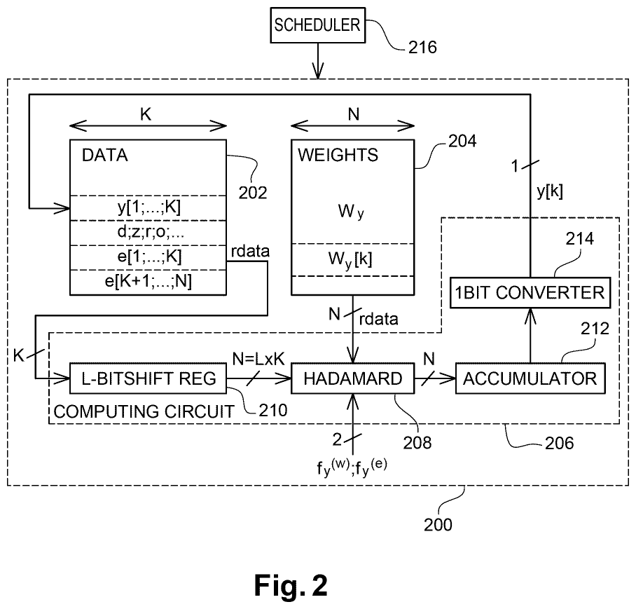

FIG. 2 is a block diagram illustrating an example of the near-memory architecture of a fully connected network, according to one embodiment of the present description. In particular, FIG. 2 shows a circuit 200 comprising two memory elements 202 (DATA) and 204 (WEIGHTS).

By way of example, memory elements 202 and 204 are two separate memories in circuit 200. By way of example, memory element 202 is configured to store a data value of length K, or in other words to store a word having K bits. In particular, memory element 202 is configured to store data computed during layer operations, such as, for example, the input vector e, the vectors x, y, s, h, u, r, z, o and any other vector of length K, or a multiple of K, involved in a layer operation. The length of these vectors stored in memory element 202 is preferably a multiple of K, such that N=L*K with L a positive integer. Advantageously, a length K is chosen corresponding to the size of a smaller vector among the vectors handled during operations, as will be explained in greater detail hereinafter.

By way of example, during execution of the neural network, the data stored in memory element 202 is dynamically deleted and written. By way of example, a layer input vector e is deleted following computing an output vector y for this same layer, and the vector y is stored in memory 202 as the input vector for the next layer. Similarly, each vector x, y, s, h, u, r, z, o computed during an operation for one layer of the network is, for example, replaced with its new version for the next layer.

By way of example, modulation and/or masking operations are performed on-line and dynamically, i.e. without prior storage of either one of the intermediate vectors involved in the operation.

By way of example, memory element 204 is N wide. Memory element 204 is configured, for example, to store one or more weight matrices, such as W_{y}, W_{z}, Wᵣ, Wₒ, Wₓ, etc., for each computing stage and for each layer of the neural network. The matrices stored in memory element 204 have rows with a length preferably equal to N, or 2N according to the examples, in order to be able to directly obtain the entirety of a row of the weight matrix stored in memory 204. In other cases, it will also be possible to take a matrix with a row size presenting a sub-multiple of N and in this case, as for the data, it will be necessary to provide an accumulator register and a sequential reading of the different parts of a row in the matrix to reconstitute a word corresponding to all the bits of a matrix row.

The circuit 200 further comprises a computing circuit 206 (COMPUTING CIRCUIT) configured, for example, to generate the components y[k] of the layer output vector y, from the data in memory 202 and from one or more matrices in memory 204. The layer output vector is then a binary vector with a value in {0,1} K.

By way of example, the computing circuit 206 comprises a circuit 208 (HADAMARD) configured to perform an operation such as a Hadamard product, from a vector included in memory 202 and a matrix, or a row or column of a matrix, included in memory 204.

According to one embodiment, the circuit is further configured to receive, for example via a 2-bit signal and during the execution of each layer, information indicating which read functions are to be applied to the data and weights before applying the scalar product operation to them. For example, for the same layer, the operations of intermediate layers, resulting in the output vector y, call on different read functions, for example the functions

$${f}_{0}^{( e )} , {f}_{0}^{( W )} , {f}_{z}^{( e )} , {f}_{z}^{( W )} ,$$

and so on. The read functions used in these operations can differ from one another. For example, the functions

$${f}_{o}^{( e )} , {f}_{z}^{( e )} ,$$

$$and {f}_{y}^{( e )}$$

are not all identical.

According to one embodiment, in the case where the integer N is strictly greater than the integer K, and is an integer multiple of the value K, the computing circuit 206 further comprises one or more shift registers 210 (L-BITSHIFT REG). In particular, considering the integer L, such as N=L×K, the computing circuit 206 comprises a number L of shift registers, each shift register being configured to shift the received data by K bits. The L shift registers enable non-contiguous data in memory 202 to be reorganized in order to provide circuit 208 with data values of size N appropriate to the operation performed with the weight matrix(es). The L shift registers also enable tensor handling in the case of two-dimensional (2D) convolution layers. The register(s) 210 further allow concatenations to be performed, allowing for example generating vectors e of length N resulting from the concatenation of several rows of memory 202, each row comprising the data of K channels in a data tensor at a spatial position, or pixel, of an image/of dimension H×W×K, where H and W respectively represent the spatial dimensions, either vertical for the value H and horizontal for the value W. The adaptation of memory 202 reading schemes to convolutions of dimension other than two is within the scope of those skilled in the art.

The circuit 208 comprises, for example, a number N of XNOR gates, configured to perform the operation when the arithmetic of the vector and the weight matrix are both in {−1,1}. In other words, the N XNOR gates are configured to perform the operation when the indication received by the circuit 208 indicates that the read functions are both the function g. For example, circuit 208 further comprises one or more AND gates configured to mask inputs when one of the two arithmetic functions is in {0,1}. In other words, the one or more AND gates enable operations to be performed, in combination with the N XNOR gates, when at least one of the read functions is the Heaviside function h.

The computing circuit 206 further comprises an accumulator 212 (ACCUMULATOR), coupled to the circuit 208 and configured to add the results of point-by-point multiplications performed by the circuit 208. According to one embodiment, the accumulator 212 is a signed adder tree.

The computing circuit 206 further comprises a converter 214 (1BIT CONVERTER) configured to binarize the value generated by the accumulator 212. In the following description, the term “binarization” refers to a two-level signal quantization operation represented by the values “0” and “1”. By way of example, converter 214 is a comparator, configured to receive digital values as inputs. In another example, the converter 214 is an ADC (Analog to Digital Converter) circuit, configured to receive analog values as inputs. By way of example, converter 214 is configured to apply the binarization function b to the value generated by accumulator 212. For example, the 214 converter is further configured to write the binarized value into memory 202.

According to one embodiment, the computing circuit 206 is then configured to be able to perform operations, such as scalar products, from binary values while respecting a configuration in a given arithmetic. The arithmetic is then not fixed, and is indicated to the circuit 206 during the execution of each layer operation. In particular, the arithmetic can vary between each layer operation. By way of example, a first scalar product is then performed in the set {−1,1}^{N}×{0,1}^{N} and a second scalar product is then performed in the set {0,1}^{N}×{0,1}^{N}, etc. In a nominal use case, each layer can use its own arithmetic and will be parameterized by only

$${f}_{y}^{( e )} and {f}_{y}^{( W )} .$$

According to one embodiment, circuit 200 comprises, or is coupled to, a scheduler circuit 216 (SCHEDULER) configured to control the execution of layer operations as for example described in relation with one of the tables Table 1 to Table 4. The scheduler circuit 216 is further configured to drive read and write memory accesses. In particular, the scheduler circuit 216 is configured to control the writing, for example sequentially, of each of the intermediate vectors, and the vectors x and/or y into memory 202. By way of example, the scheduler circuit 216 is a coprocessor in a system encompassing the circuit 200 and the scheduler circuit 216. The scheduler circuit 216 also enables the various layer operations performed by the different elements of the circuit 200 to be sequenced.

In operation, the scheduler circuit 216 is configured, for example, to control the computing circuit 206 to perform several computation rounds, and thus generate the vectors corresponding to the processing to be performed, such as one or more of the processes set out in tables Table 1 to Table 4 below. The vectors generated in each round are stored in memory 202, for example, and at the end of processing, the output vector y is available in memory 202, for example.

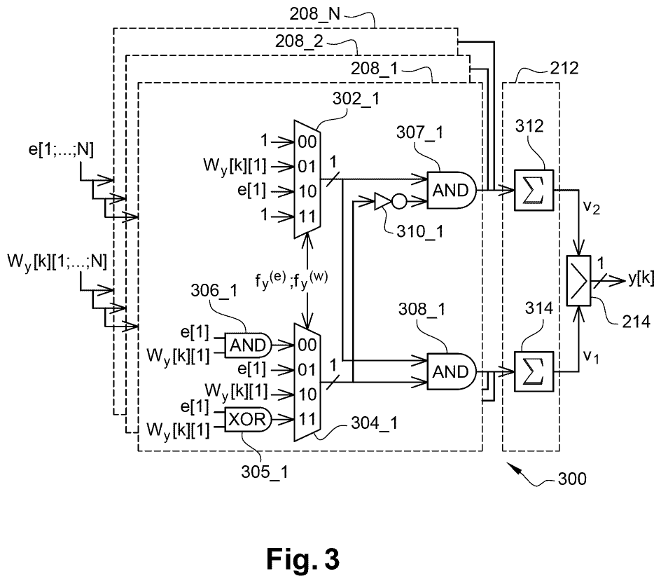

FIG. 3 is a diagram illustrating an example circuit 300 implementing a requantized scalar product operator. In particular, the circuit 300 illustrates an example of how the circuit 208, accumulator 212 and converter 214 shown in FIG. 2 are implemented in the form of a two-channel computation. These two channels are separated, for example so that computations can be performed regardless of the arithmetic used, i.e. regardless of the read functions

$${f}_{y}^{( e )} and {f}_{y}^{( W )}$$

used. For example, circuit 208 comprises a number N of sub-circuits 208_1 to 208_N.

In the example illustrated in FIG. 3, the circuit 300 is configured to generate a component y[k], of the output vector y, based on an input vector e stored in memory 202 and the k-th row of a weight matrix W_{y}, stored in memory 204 and the indication of two read functions

$${f}_{y}^{( e )} and {f}_{y}^{( W )} .$$

In particular, circuit 300 is configured to perform operation

$$y [ k ] = b ( {f}_{y}^{( W )} ( {W}_{y} [ k ] ) {f}_{y}^{( e )} ( e ) ) ,$$

for any k∈{1, . . . , K}.

Each circuit 208_i, i∈{1, . . . , N}, is configured to receive the i-th component e[i] of the input vector e and the element W_y[k][i]. These values are supplied, for example, to multiplexers 302_i and 304_i. By way of example, multiplexers 302_i and 304_i are configured to select a configuration, from configurations 00, 01, 10 and 11, based on the indication of read functions

$${f}_{y}^{( e )} and {f}_{y}^{( W )} .$$

By way of example, configuration 00 represents the configuration in which

$${f}_{y}^{( e )} = h$$

$$and$$

$${f}_{y}^{( W )} = h ,$$

configuration 01 represents the configuration in which

$${f}_{y}^{( e )} = h$$

$$and$$

$${f}_{y}^{( W )} = g ,$$

configuration 10 represents the configuration in which

$${f}_{y}^{( e )} = g and {f}_{y}^{( W )} = h ,$$

and configuration 11 represents the configuration in which

$${f}_{y}^{( e )} = g and {f}_{y}^{( W )} = g .$$

The values e[i] and W_{y}[k][i] are further provided to an XOR gate 305_i configured to perform the operation e[i] XOR W_{y}[k][i] as well as to an AND gate 306_i configured to perform the operation e[i] AND W_{y}[k][i].

By way of example, in configuration 00, the multiplexer 302_i is configured to select a value equal to 1 and the multiplexer 304_i is configured to select the output of the AND gate 306_i. In configuration 01, the multiplexer 302_i is, for example, configured to select the value W_{y}[k][i] and the multiplexer 304_i is, for example, configured to select the component e[i]. In configuration 10, the multiplexer 302_i is, for example, configured to select the component e[i] and the multiplexer 304_i is, for example, configured to select the component W_{y}[k][i]. In configuration 11, multiplexer 302_i is, for example, configured to select a value equal to 1 and multiplexer 304_i is, for example, configured to select the output of XOR gate 305_i.

By way of example, multiplexer 302_i is configured to transmit the selected value to one input of an AND gate 307_i and to one input of an AND gate 308_i. The multiplexer 304_i is, for example, configured to transmit the selected value to the other input of the gate 308_i and to the input of an inverter 310_i. The inverter 310_i is then configured to invert the value, i.e. to generate the value 0 when the value supplied is equal to 1 and vice versa, and to supply it to the other input of gate 307_i.

Gate 307_i is then configured to apply the AND operation to the values forwarded by multiplexer 302_i and inverter 310_i. Gate 308_i is then configured to apply the AND operation to the values forwarded by multiplexers 302_i and 304_i.

Each of the gates 307_i and 308_i of each of the subcircuits 208_1 to 208_N is configured to supply the generated value to the accumulator 212. In particular, gates 307_1 to 307_N are configured to supply the generated values to an adder circuit 312, and gates 308_1 to 308_N are configured to supply the generated values to an adder circuit 314. Adders 312 and 314 are respectively configured to generate a value v₂, v₁, corresponding, for example, to the sum of the values supplied by gates 307_1 to 307_N and 308_1 to 308_N.

Adders 312 and 314 are then configured to supply values v₁ and v₂ to comparator 214. By way of example, the comparator 214 is configured to generate the binary value 1 in the event that the value v₁ is greater than the value v₂, and to generate the binary value 0 in the opposite case. The binary value generated corresponds to the scalar product

$$y [ k ] = b ( {f}_{y}^{( W )} ( {W}_{y} [ k ] ) {f}_{y}^{( e )} ( e ) ) .$$

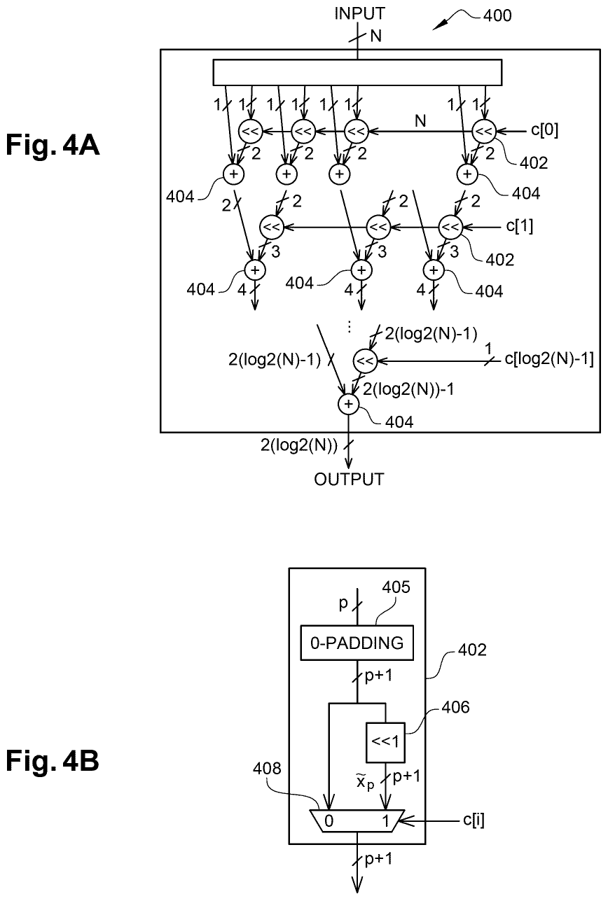

FIG. 4A is a diagram illustrating an example of adder tree 400, according to one embodiment of the present description. In particular, adder tree 400 is an example implementation of adder circuits 312 and 314. According to one embodiment, adder tree 400 comprises a number log₂ (N) of stages, each stage comprising one or more programmable bit shift circuits 402 and an equal number of adders 404.

By way of example, the adder tree 400 is configured to receive a word (INPUT) of N bits and to generate an output value (OUTPUT), based on a vector c=(c [0], c[1], . . . , c [log₂ (N)−1]) of length log₂ (N). The word received by circuit 400 corresponds to the N bits forwarded by circuits 208_1 to 208_N. For example, in a first stage, the adder tree 400 comprises a number N/2 of programmable bit shift circuits 402. By way of example, the adder 400 is configured to supply each odd-numbered or even-numbered bit to a shift circuit 402. In other words, every second bit of the input word is supplied to a shift circuit 402. In this first stage, each shift circuit 402 therefore receives one bit as input.

FIG. 4B is a diagram illustrating an example programmable bit shift circuit 402, according to one embodiment of the present description.

Each shift circuit 402 is configured to receive a word comprising bits xₚ, for example a number p of bits, p being an integer greater than or equal to 1. The circuit 402 comprises a circuit 405 (0-PADDING) configured to add a bit to the word xₚ. By way of example, circuit 405 is configured to generate a p+1 bit word the most significant bit of which is set to the value 0, and the p least significant bits of which correspond to the word xₚ. By way of example, circuit 405 is configured to apply the so-called “0 Maximum Padding” method to the received word.

Each shift circuit 402 comprises, for example, a shift register 406, configured to generate a word \tilde{x}ₚ, corresponding to the multiplication by two of a big-endian unsigned integer by the word xₚ, by shifting the input word xₚ by one bit and setting a “0” on the least significant bit. Each shift circuit 402 further comprises, for example, a multiplexer 408. The multiplexer 408 is, for example, configured to select a word, from among the word xₚ and the word \tilde{x}ₚ, on the basis of a value of a bit c [i] of the word c at index i. For example, if the value of the bit c [i] is 0, the multiplexer 408 is configured to select the word xₚ and if the value of the bit c [i] is 1, the multiplexer 408 is configured to select the word \tilde{x}ₚ.

By way of example, the shift circuits 402 of the first stage of tree 400 shown in FIG. 4A are therefore configured to generate 2-bit words. Each shift circuit 402 is further configured to supply the generated word to an adder 404. By way of example, each adder 404 of the first stage of tree 400 is further configured to receive a bit of the input word that has not been supplied to a shift circuit 402. By way of example, for each bit of rank n in the input word supplied to a shift circuit 402, the bit of rank n−1 is supplied to the adder 404 receiving the word generated by said shift circuit, from the bit of rank n. Each adder 404 is configured to generate a word by adding the two values received. By way of example, the word generated by an adder 404 of the first stage of tree 400 is of length 2. Indeed, the maximum value achievable on the first stage, in integer representation, is 2+1=3 and can be represented in binary by word 11, which can therefore be coded on 2 bits. From the next stage onwards, each adder 404 is configured to generate a word comprising a bit additional to that supplied by the shift circuit 402. On each of these stages, the maximum achievable value exceeds the dynamic range associated with the number of bits in the word supplied by the shift circuit 402.

By way of example, following the processing of the input word by the first stage of tree 400, N/2 words of 2 bits are supplied to a second stage of tree 400.

The operation of the second stage of tree 400 is, for example, identical to that of the first stage. Each adder 404 in the second stage is then configured to forward the generated word to, depending on its position in the tree 400, a shift circuit 402 in the second stage or an adder 404 in the second stage.

The last stage of the tree 400, i.e. the log₂ (N)-th stage, then comprises a single shift circuit 402 and a single adder 404. This last adder 404 is configured to generate an output word (OUTPUT) from the tree 400, comprising for example 2 log₂ (N) bits. As with the previous stages, the adder 404 in the last stage is configured to generate the output word by adding the word generated by the shift circuit 402 in the last stage to a value provided by one of the two adders 404 in the penultimate stage. In particular, since the penultimate stage comprises two adders 404, one is configured to supply the word it generates to the shift circuit 402 in the last stage, and the other is configured to supply the word it generates to the adder 404 in the last stage. The shift circuit 402 in the last stage is then configured to make a selection based on the value of bit c [log₂ (N)−1].

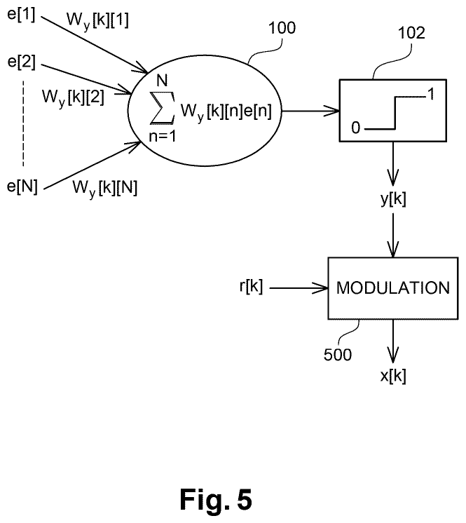

FIG. 5 is a block diagram showing the rebinarized scalar product described in relation to FIG. 1, followed by a modulation operation.

According to one embodiment, the binarized output y[k] is supplied to a modulation block 500 (MODULATION). By way of example, the modulation block 500 is configured to receive a vector, such as the intermediate data r, for example. The modulation block 500 is then configured to perform a modulation operation between each output coefficient y[k] and each coefficient r[k] of the vector r. By way of example, block 500 generates the coefficient x[k], corresponding for example to y[k] when the value of r[k] is equal to 1, or corresponding to the value 0 as r[k] is equal to 0. The vector x then corresponds to the point-by-point product between the vectors y and r.

In the example described in relation to the table Table 1, block 500 is configured to generate each coefficient of the vector x by applying the modulation operation between ƒₓ(y[k]) and ƒₓ(r[k]). The generated vector x is then equal to ƒₓ(y)·ƒₓ(r).

By way of example, each coefficient of the vector y is supplied to block 500 directly and without first being stored in a memory.

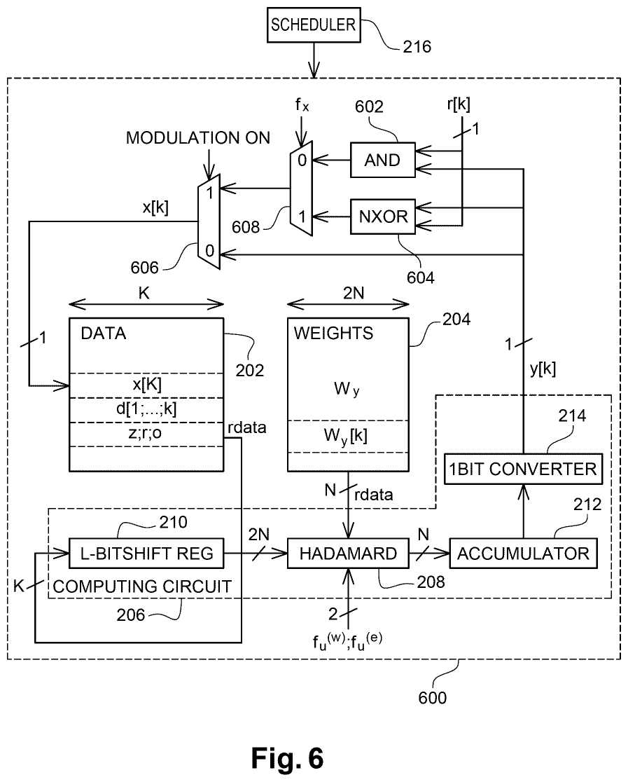

An example of the implementation of block 500 is described in detail in relation to FIG. 6.

FIG. 6 is a block diagram illustrating a circuit 600 configured to perform layer operations comprising, inter alia, modulation operations, according to one embodiment of the present description. By way of example, circuit 600 illustrates embodiments of circuit 200, and comprises elements 202 to 214 described in relation with FIG. 2. The circuit 600 further comprises, or is coupled to, the scheduler circuit 216 configured to control and drive the execution of layer operations in relation to, for example, one of tables 1 to 4.

By way of example, the computing circuit 206 of the circuit 600 is further configured to compute the components of one or more “intermediate” vectors corresponding, for example, to the vectors y, z, r, and o described in table Table 1. By way of example, circuit 208 of circuit 600 is configured to perform a point-to-point product, between the input vector d and a row of a weight matrix W_{y}. In particular, circuits 208 and 212 of circuit 600 are configured to perform the scalar product between the input vector d and a row of a weight matrix W_{y} on the basis of the indication of read functions

$${f}_{u}^{( e )} and {f}_{u}^{( W )}$$

among functions g and h. The computing circuit 206 sequentially supplies the components y[k] to a first input of each of the gates 602 and 604. By way of example, the circuit 206 is further configured to supply each component y[k] to a first input of a multiplexer 606.

Gates 602 and 604 are further configured to receive, sequentially, at a second input, components r[k] of a binary vector r. Gate 602 is then, for example, configured to perform, on each reception of a component y[k], an operation of AND type between the component y[k] and the component r[k]. Gate 604 is then, for example, configured to perform, on each reception of a component y[k], an XNOR type operation between the component y[k] and the component r[k]. The values generated by gates 602 and 604 are then forwarded to a multiplexer 608 configured to select the output of gate 602, or the output of gate 604, as a function of a read function fr. The multiplexer 608 is then configured to forward the selected value to a second input of the multiplexer 606. The multiplexer 606 is then configured to generate the output coordinate x[k] of the binary vector x by selecting the component y[k], or the output of the multiplexer 608, based on a signal MODULATION ON. In particular, gates 602 and 604 and multiplexers 606 and 608 define an example implementation of modulation block 500.

In one example, when the layer operation performed incorporates a modulation corresponding to masking, different from the “multiplexing” masking defined above, the function ƒₓ chosen will be the Heaviside function h. When the layer operation performed incorporates modulation corresponding to binary modulation, the function ƒₓ chosen will be the function g.

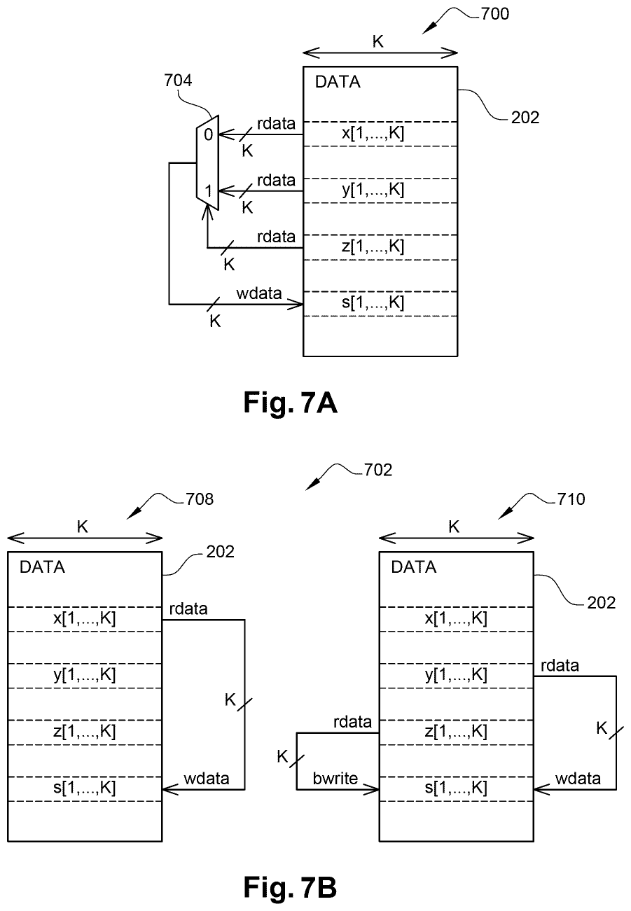

FIG. 7A schematically illustrates a sequence of operations 700 for implementing a binary masking mechanism, possibly using a multiplexing circuit 704, but which can also be implemented without a multiplexing circuit.

FIG. 7B schematically illustrates another example sequence of operations 702, based on reads and writes of a memory circuit also enabling a masking mechanism to be implemented without additional hardware.

In particular, FIGS. 7A and 7B illustrate operations of a binary masking mechanism that can be incorporated into the circuit 200 and/or 600 and linked to the memory element 202 described in relation to FIGS. 2 and/or 6. FIGS. 7A and 7B illustrate sequences of operations 700 or 702, advantageously implemented by the scheduler circuit 216.

By way of example, the masking mechanism acts on two data vectors simultaneously, for example the vectors x and y described in table Table 1, and stored in memory 202. The masking mechanism is further controlled by a masking vector z, stored in memory 202.

By way of example, a vector s=\tilde{z}·x+z· y, as described in table Table 1, corresponds to the masking of vectors x and y, controlled by vector z. By way of example, computing the vector s is performed either according to one of the sequences of operations 700 shown in FIG. 7A, or according to the sequence of operations 702 shown in FIG. 7B.

According to one embodiment illustrated in FIG. 7A, the sequence of operations 700 orchestrated by the scheduler circuit 216 is as follows when using a multiplexing circuit placed at the periphery of the memory element 202. In practice, the multiplexing circuit consists of K multiplexers with 2 inputs, each controlled by a selection bit. First, the vector x and then the vector y are read from memory element 202. The values read are placed in registers, not shown, at the input of multiplexer circuit 704. The vector z is then read from memory element 202. The values of vector z are used to control the multiplexer 704. The data value present at the output of the multiplexing circuit, following this selection on the basis of the vector z, are then written into memory element 202 as forming the vector s.

According to another alternative embodiment, also illustrated in principle in FIG. 7A, the sequence of operations 700 orchestrated by the general control device is performed without the use of a multiplexer. To this end, the vectors x, y, and z are read from memory. Then, depending on the composition of the computation means of the general control device, the equivalent of the multiplexing function described above is implemented in hardware or software. Note that it may be possible to potentially reduce the number of readings from memory 202 by first reading the vector z, then reading all or only some of the vectors x and y. So, if, for example, all the bits of the vector z are at the same value, only one complete reading of the vector x or y can be performed, the other reading not being useful. Finally, as before, the result is written into memory element 202 at the location where the vector s is stored.

The operations hereinabove described are then repeated for each value k between 1 and K. The scheduler circuit 216 is, for example, configured to control the storage of each component of the vector x in a buffer memory, and then, once the vector has been fully generated, to control its writing into memory 202. In another example, the scheduler circuit 216 is configured to control the writing of each component of the vector, one by one and as soon as they have been generated, into memory 202.

According to one embodiment, circuit 704 is configured to write vector s into memory 202. Circuit 704 comprises, for example, a number K of parallel multiplexers. For example, if the vector x is not reused in a subsequent computation, the vector s is written directly into memory 202 to replace the vector x.

According to one embodiment, circuit 702 comprises memory 202 configured so that signals provided from reading data (rdata) and controlling write (bwrite) perform a scheduling allowing the masking mechanism to be performed in a reduced number of clock strokes and using standard signals for controlling memory tile.

In the example shown in FIG. 7B, memory 202 is a memory configured to implement masking operations such as those described in more detail in the patent U.S. Pat. No. 6,075,721, for example. The signals resulting from data reading, write controlling and data to be written then perform a two-step consecutive scheduling 708 and 710.

The sequence of operations 708 is driven by the scheduler circuit 216. In this example, memory 202 stores, for example, the vectors y, x, and z as well as the vector s corresponding, for example, to the previous round. In order to generate the vector s for the current round, memory 202 is configured to perform masking s=y·z+x· Z. To this end, memory 202 is configured to read the vector x (rdata), and copy it as write data (wdata) by supplying it to a so-called “data” input of memory 202 in place of the vector s of the previous round.

The sequence of operations 710, following sequence 708, comprises the reading of vectors y and z (rdata). The vectors y and z are, for example, temporarily stored in one or more buffer memories, external to the matrix 202. The vector z is supplied to a “mask” input of memory 202. Memory 202 then reads component by component the vectors y and z stored in the external buffer memories, and rewrites the components s[k] in memory 202 as s[k]=y[k] when z[k]=1 and s[k]=0 when z[k]=0. By way of example, component-by-component reading by memory 202 is performed in parallel. Thus, following operations 708 and 710, the vector s stored in memory 202 corresponds to the masking s=y·z+x·z.

According to one embodiment, computing the vector s takes place following the generation of the vector y, or sequentially, following the generation of each component y[k]. Writing binary values describing the components of the vectors stored in memory 202 is then sequentially performed, rather than in parallel.

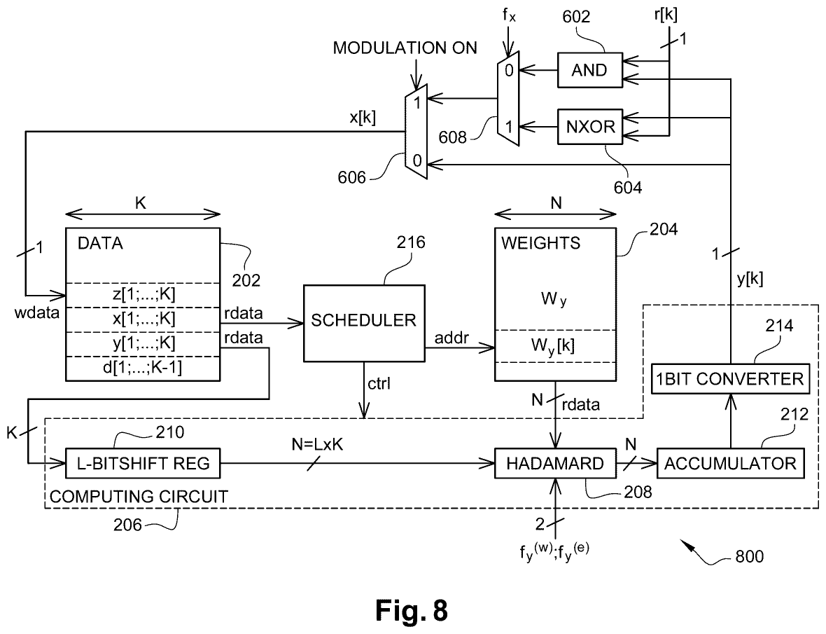

FIG. 8 is a block diagram illustrating an example circuit 800 of a fully connected layer incorporating a modulation mechanism on a vector from an intermediate computation and enabling a masking mechanism to be performed by conditional updating of the output vector, according to one embodiment of the present description.

According to one embodiment, circuit 800 comprises scheduler circuit 216. By way of example, the scheduler circuit 216 is configured to control computing a vector s, derived from the masking mechanism, such as

$$s = \overline{z} \cdot b ( {f}_{x} ( b ( {f}_{y}^{( w )} ( {W}_{y} ) {f}_{y}^{( e )} ( d ) ) ) \cdot {f}_{x} ( r ) ) + z \cdot s .$$

By way of example, the vector s represents a layer operation illustrated in relation to the table Table 1. In the example illustrated in FIG. 7B, the scheduler circuit 216 is configured to receive the vector z and, on the basis of the values of each component z[k] of the vector z, to directly control the reading, or not, of the k-th row of a weight matrix W_{y}, stored in memory 204. This makes it possible to perform only the computations required to update the vector s using the components of the vector x corresponding to the components of the vector z being zero, at their corresponding places in the vector s, i.e., for each index k such as z[k]=0, we nave

$$s [ k ] = b ( {f}_{x} ( b ( {f}_{y}^{( w )} ( {W}_{y} ) {f}_{y}^{( e )} ( d ) ) ) \cdot {f}_{x} ( r [ k ] ) ) .$$

In particular, and as described in relation to FIG. 6, computing the vector s is performed in several computation rounds by the circuit 206. The scheduler circuit 216 is then configured to reduce the computation latency and power consumption of circuit 800 by avoiding performing unnecessary computations.

In the example where the scheduler is configured to control the generation of the vectors described in relation to the table Table 1, the memory 202 comprises, for example, initially, the vectors sₜ₋₁ and dₜ. Memory 204 comprises, for example, the weight matrices W_{z}, Wₒ, and W_{y}. By way of example, the vector rₜ is computed entirely by the circuit 206. The scheduler circuit 216 is then configured to supply the indication of the read functions

$${f}_{r}^{( W )} and {f}_{r}^{( e )}$$

to the circuit 208 for performing the scalar products between the vector

$${f}_{r}^{( e )} ( {d}_{t} )$$

and the rows

$${f}_{r}^{( W )} ( {W}_{z} [ k ] ) .$$

The vector rₜ is then stored in memory 202, for example. The scheduler circuit 216 is further configured to control computing a component of the vector zₜ, for example z[1] on the basis of the read functions

$${f}_{z}^{( W )} and {f}_{z}^{( e )} .$$

By way of example, the scheduler circuit 216 is configured to provide the indication of the read functions

$${f}_{z}^{( W )} and {f}_{z}^{( e )}$$

to the circuit 208 for performing the scalar product between the vector ƒ_{z}(e)(dₜ) and the row

$${f}_{z}^{( W )} ( {W}_{z} [ 1 ] ) .$$

The component zₜ[1] is then, for example, stored in memory 202. In another example, the K components of the vector zₜ are computed and the vector zₜ is stored in memory 202. The scheduler circuit 216 is further configured to control the computation, by the circuit 206, and providing indication of the read functions

$${f}_{y}^{( e )} and {f}_{y}^{( W )} ,$$

of the component yₜ[1]. Scheduler circuit 216 is then configured to activate the signal MODULATION ON in order to activate block 500. Block 500 is then configured to generate the component xₜ[1] by performing a modulation between ƒₓ(yₜ[1]) and ƒₓ(rₜ[1]). The component yₜ[1] is then not stored in memory 202 following its computation by circuit 206. Memory 202 is then, for example, configured to perform masking, for example as described in relation to FIG. 7A or 7B. The value zₜ[1] is read and the value of the component sₜ₋₁[1] is overwritten, in the case where z_t[1]=0, by the component xₜ[1]. The value of the component sₜ[1] for the currentsₜ vector is then equal to xₜ[1]. In the case where zₜ[1] is equal to 1, the component sₜ₋₁[1] is not overwritten, and becomes the value of the component sₜ[1] for the current vector sₜ.

The scheduler circuit 216 is further configured to control the computation, by the computing circuit 206, of the component oₜ[1] on the basis of the read functions

$${f}_{o}^{( W )} and {f}_{o}^{( e )} .$$

The scheduler circuit 216 is then configured to activate the signal MODULATION ON in order to activate block 500. The component oₜ[1] is, for example, supplied directly to the modulation block 500, which is configured to generate the component hₜ[1] by performing a modulation between ƒₕ(sₜ[1]) and ƒₕ(oₜ[1]). The component oₜ[1] is then not stored in memory 202 following its computation by circuit 206. The vector hₜ is then updated in memory 202 following storage of the component hₜ[1].

Circuit 800 then performs K−1 further computation rounds, in order to compute all the components of the vectors sₜ and hₜ.

Advantageously, the sequences of operations described above perform a scheduling that enables the masking mechanism to be implemented in a reduced number of clock strokes and using standard signals for controlling a memory tile by the scheduler circuit 216. In addition, intermediate data can be used directly, for example for modulation operations, without having to be stored beforehand, thus saving both space area and time.

One advantage of the described embodiments is that they enable near-memory layer operations, and in particular intermediate operations, to be performed by varying the arithmetic used, between each layer and between each operation, for the weight matrices and vectors handled.

Another advantage of a near-memory implementation is that the canonical control signals of the memory plane can be used efficiently for some or all of the variants described above.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A circuit comprising:
a first memory element configured to store a first data value; a second memory element configured to store a first weight matrix in association with a first layer of an artificial binary neural network;
a computing circuit configured to:
a) receive the first data value and the k-th row, of the first weight matrix;
b) receive a first control signal, indicating the nature of each of the first and second read functions, from among at least the first and second reference functions, the first and second reference functions each being associated with two-valued arithmetic;
c) generate a first vector by applying the first read function to the k-th row of the first weight matrix and a second vector by applying the second read function to the first data value; and
d) generate a k-th component of a first output vector on the basis of the first and second vectors.

2. The circuit according to claim 1, wherein the first reference function has values in {−1,1} and the second reference function has values in {0,1}.

3. The circuit according to claim 1, configured to, following generation of the k-th component of the first output vector, control storage of the k-th component in the first memory element.

4. The circuit according to claim 1, further comprising:
a first logic gate configured to apply an operation of AND type between the k-th component of the first output vector, forwarded by the computing circuit, and a component of a binary vector;
a second logic gate configured to apply an operation of XNOR-type between the k-th component of the first vector, forwarded by the computing circuit, and the component of the binary vector;
a first multiplexer configured to select the output of the first logic gate, or the output of the second logic gate, on the basis of a control signal indicating the nature of a third read function among the first and second reference functions;
a second multiplexer configured to generate a k-th component of a second output vector by selecting the k-th component of the first vector, supplied by the computing circuit, or the output of the first multiplexer, on the basis of a modulation signal.

5. The circuit according to claim 1, further comprising a scheduler circuit configured to:
receive a component of a vector stored in the first memory element; and
on the basis of the value of the component, control the reading, from the second memory element, of the k-th row of the first weight matrix.

6. The circuit according to claim 1, wherein the computing circuit comprises:
a number N of multiplier circuits each configured to receive the first and second read functions, and each configured to generate an output scalar based on a component of a vector and a component of a weight matrix;
an accumulator circuit configured to sum the output scalars provided by the plurality of multiplier circuits; and
a converter configured to convert the value generated by the accumulator circuit into a binary value.

7. The circuit according to claim 6, wherein the accumulator comprises an adder tree, comprising a plurality of shift circuits and configured to generate a scalar, corresponding to the scalar product between the first and second vectors, increased by a gain being a power of 2.

8. The circuit according to claim 1, wherein the first data value is of length N, N being an integer, and is stored contiguously by vectors of lengths K, K being a divisor of the value N, and wherein the k-th row, of the first matrix is of length N, and wherein the computing circuit comprises a number L=N/K of shift registers coupled to the first memory element and is configured to, following receiving a sequence of vectors of the first data value, convert said first data value into a vector of size N, by concatenating vectors of size K, wherein the shift registers are, for example, further configured to concatenate the first data value of size K with a sequence of N−K bits each equal to 1, or 0.

9. The circuit according to claim 8, wherein each of the multiplier circuits comprises a logic gate of the NXOR and/or AND type configured to multiply a component of the first data value and an element of the first weight matrix associated with the first layer.

10. The circuit according to claim 5, wherein the first memory element is further configured to store a masking vector, the scheduler circuit being configured to:
if the k-th component of the masking vector is equal to 0, control storage of the k-th component of the first data value as the k-th component of the first output vector; and if the k-th component of the masking vector is equal to 0, cause the execution of steps a) to c).

11. The circuit according to claim 10, wherein the first memory element is a memory configured to implement masking operations.

12. The circuit according to claim 1, wherein the second memory element further stores a third weight matrix associated with a second layer of the neural network, and wherein the computing circuit is further configured to:
select, following reception of a second control signal, fifth and sixth read functions, from among the first and second reference functions;
generate a fifth vector by applying the fifth read function to a row, or column, of the third weight matrix and a sixth vector by applying the sixth read function to an output vector of a previous layer stored in the first memory element; and
generate a third output value based on the fifth and sixth vectors.

13. The circuit according to claim 1, wherein the first reference function is defined by g:u→u and the second reference function is defined by h:u→2u−1.

14. A method comprising:
supplying a first data value stored in a first memory element of a circuit and the k-th row of a first weight matrix associated with a layer of a binary artificial neural network to a first computing circuit of the circuit;
providing an indication, via a control signal, of the nature of a first and a second read function, among a first and a second reference function;
generating, by the first computing circuit, a first vector by applying the first function to the k-th row of the weight matrix and of a second vector by applying the second function to the first data value,
generating a k-th component of a first output vector on the basis of the first and second vectors, the first and second reference functions each being associated with two-valued arithmetic.

15. The method according to claim 14, wherein the first computing circuit comprises a plurality of multiplier circuits and an accumulator configured to generate a scalar by performing a scalar product between the first and second vectors, wherein, the first computing circuit comprises, for example, a converter configured to convert the scalar into a binary value.

16. The method according to claim 14, further comprising:
reading, by a second computing circuit, the value of a first component of the first data value, the first output value and a first masking value, stored in the first memory element; and
controlling, on the basis of the first masking value and by the second computing circuit, the writing of a first masked value into the first memory element, corresponding either to the first component of the first data value, or to the k-th component of the first output vector.

17. The method according to claim 16, wherein writing the first masked value comprises:
deleting the first component of the first data value; and
writing the masked first value to the address of the first component of the first data value into the first memory element.

18. The method according to claim 16, further comprising, after writing the first masked value:
generating a k+1-th output component of the first output vector and storing it in the first memory element;
reading, by the second computing circuit, the value of a k+1-th component of the first data value, of the k+1-th component of the first output vector, and a second masking value, stored in the first memory element; and
controlling, on the basis of the second masking value and by the second computing circuit, the writing of a second masked value into the first memory element, corresponding either to the k+1-th component of the first data value, or to the k+1-th component of the output vector.
